(19) United States
(12) Patent Application Publication
(10) Pub. No.: US 2011/0291111 A1
(43) Pub. Date: Dec. 1, 2011

(54) SEMICONDUCTOR DEVICE AND SEMICONDUCTOR DEVICE MANUFACTURING METHOD

(75) Inventors: Shuichi NAGAI, Osaka (JP); Takeshi FUKUDA, Osaka (JP); Hiroyuki SAKAI, Kyoto (JP)

(73) Assignee: PANASONIC CORPORATION, Osaka (JP)

(21) Appl. No.: 13/206,908

(22) Filed: Aug. 10, 2011

Related U.S. Application Data
(63) Continuation of application No. PCT/JP2009/006624, filed on Dec. 4, 2009.

(30) Foreign Application Priority Data
Feb. 20, 2009 (JP) 2009-038409
Feb. 20, 2009 (JP) 2009-038670

(51) Int. Cl. H01L 29/161; H01L 23/495; H01L 21/78

(52) U.S. Cl. 257/77; 438/463; 257/676; 257/E29.084; 257/E21.599; 257/E23.031

(57) ABSTRACT

A chip size package includes: a radio frequency substrate having a radio frequency semiconductor circuit formed on a principal surface; a semiconductor cover substrate arranged at a position facing the principal surface of the radio frequency substrate; and a joining frame arranged in a manner such as to surround the radio frequency semiconductor circuit between the radio frequency substrate and the semiconductor cover substrate, the joining frame joining the radio frequency substrate and the semiconductor cover substrate, wherein: the radio frequency substrate further has a wire formed on a surface opposite to the principal surface; and the radio frequency semiconductor circuit and the wire are electrically connected to each other through a via hole penetrating through the radio frequency substrate in a thickness direction thereof.

### CROSS REFERENCE TO RELATED APPLICATION

This is a continuation application of PCT application No. PCT/JP09/006624 filed on Dec. 4, 2009, designating the United States of America.

### BACKGROUND OF THE INVENTION

(1) Field of the Invention

The present invention relates to a semiconductor device for use in a wireless communication device, etc. and a method of manufacturing the semiconductor device, and more particularly relates to a semiconductor device package of a semiconductor integrated circuit used for application to high frequencies.

(2) Description of the Related Art

In recent years, with progress of downsizing and integration of semiconductor chips, research and development has been actively carried out on ultra-compact chip size packages (CSP) that has a size equal to a size of a chip or is itself a chip serving as a package (Japanese Unexamined Patent Application Publication No. H9-64236 hereinafter referred to as Patent Document 1).

FIG. 20 shows a semiconductor chip 1000 with a conventional chip size package structure. The semiconductor chip 1000 is obtained, as shown in FIG. 20, by forming an insulation film on a wafer, forming a wire, forming a sealing resin film 1001, forming a connecting post 1002, bonding a bump (soldered ball) 1003, and then performing dicing into a chip shape. This enables reduction in package assembly cost of the semiconductor chip 1000 and drastic reduction in the number of parts, thus providing a very low-cost packaging method. In particular, wafer-level packaging that permits packaging in a wafer state is an extreme packaging method.

Such a chip size package is assumed to be mounted on, for example, a printed substrate through flip chip. That is, a distance over which the semiconductor chip 1000 and a mounting substrate 1004 on which the semiconductor chip 1000 is mounted are connected to each other is very short. Thus, it can be said to be very effective mounting for a radio frequency region since undetermined wire connection can be avoided and terminal connection loss can be minimized in a radio frequency chip with a chip characteristic having a great influence on terminal connection condition.

Used as configuration of such a chip mounted through the flip chip on a semiconductor circuit is a coplanar wiring structure in which a signal wire and a ground are formed on the same plane. This coplanar wiring requires a large ground region on a chip surface, which is therefore disadvantageous in terms of a chip area utilization ratio. On the other hand, in a case where a semiconductor chip with a microstrip wiring structure where a ground is on a chip rear surface, a ground of a mounting substrate and a ground surface of a radio frequency chip are separated from each other with a distance therebetween. Thus, the grounds easily turn into a floating state and become unstable, thus raising a problem that a radio frequency characteristic greatly deteriorates. As a chip structure that solves such a problem, suggested in Japanese Unexamined Patent Application Publication No. 2002-9193 referred to as Patent Document 2 is a chip structure where a terminal of a circuit is outputted onto a chip rear surface through a via hole.

A nitride semiconductor of a direct transmission type which has a wide band gap and which contains gallium nitride (GaN), aluminum nitride (AIN), indium nitride (InN), and also a mixed crystal substance expressed by general formula (InₓAl₁₋ₓ)yGa_{1-y}N gets a lot of attention as a radio frequency semiconductor chip since it has a great breakdown electric field and a great saturated electron speed. In a case where this nitride semiconductor is used for application to high frequencies, in order to realize a transfer line path with low loss in a radio frequency region, a sapphire substrate as a material with low dielectric loss is used. For example, reported in 2008 IEEE MTT-S Int. Microwave Symp, Dig. pp. 1293-1296 referred to as Non-Patent Document 1 is a radio frequency MMIC (Monolithic Microwave Integrated Circuit) formed of GaN.

The radio frequency semiconductor chip described above does not function as a system on its own, and thus is connected to a silicon LSI chip for signal processing or an antenna element of a wireless input and output device for use in the system. For example, a multichip package has been suggested in Japanese Unexamined Patent Application Publication No. 2002-343930 referred to as Patent Document 3, but it is still a very complicated structure, and thus there have been demands for a low-cost, compact multichip package.

### SUMMARY OF THE INVENTION

The chip size package with the configuration described above is sealed with resin in many cases. However, it is difficult to keep airtightness with the resin, thus raising a problem that it cannot be used for application requiring high reliability.

Moreover, the radio frequency semiconductor circuit chip such as the GaN semiconductor described above as the conventional art generally does not function as a system on its own. Thus, it needs to be connected to an LSI (silicon integrated circuit) chip for signal processing formed of a silicon semiconductor or antennas for inputting and outputting. The antenna parts handle high frequencies, and thus an antenna substrate material with a favorable radio frequency characteristic is required. Loss of connection between the radio frequency semiconductor chip and the antennas has a great influence on characteristics of the entire system, and thus it is desired that the antennas and the radio frequency semiconductor circuit be integrated to minimize the connection loss.

However, with strong demands for downsizing, cost reduction, and simplification of a wireless transmitting and receiving device in recent years, it has been difficult to realize a chip size package of a multichip type where an antenna, a silicon integrated circuit, and a radio frequency semiconductor circuit are integrated.

Thus, in view of such situation, the present invention has been made, and it is an object of the invention to improve airtightness to thereby provide a semiconductor device with high reliability and a method of manufacturing this semiconductor device.

It is also an object of the invention to provide a semiconductor device which has a structure with high packaging density and which is a chip size package where an antenna, a silicon integrated circuit, and a radio frequency semiconductor circuit are integrated, and a method of manufacturing this semiconductor device.

A semiconductor device according to one aspect of the invention includes: a radio frequency substrate having a principal surface on which a radio frequency semiconductor circuit is formed; a semiconductor substrate arranged at a position facing the principal surface of the radio frequency substrate; and a joining frame arranged between the radio frequency substrate and the semiconductor substrate in a manner such as to surround the radio frequency semiconductor circuit, the joining frame joining the radio frequency substrate to the semiconductor substrate. Further, formed on a surface opposite to the principal surface of the radio frequency substrate is a wire. The radio frequency semiconductor circuit and the wire are electrically connected to each other through the via hole penetrating through the radio frequency substrate in a thickness direction thereof.

As a result, the radio frequency semiconductor circuit is arranged in the airtight region laid out by the radio frequency substrate, the semiconductor substrate, and the joining frame, which can therefore realize a radio frequency chip with high airtightness and high reliability. Moreover, a terminal of the radio frequency semiconductor circuit arranged in the airtight region can be pulled to outside. A form of the connection between the radio frequency semiconductor circuit and the wire is not limited to the via hole, but may be, for example, electromagnetic coupling.

The semiconductor substrate may be a silicon semiconductor substrate. As a result, a radio frequency circuit chip with small unnecessary electromagnetic radiation and high performance can be realized. The use of the silicon semiconductor substrate with high specific resistance can reduce loss of the radio frequency semiconductor circuit.

Preferably, a gap between the radio frequency semiconductor circuit and the semiconductor substrate is 10 μm or above. The specific resistance of a silicon semiconductor substrate is generally 100 Ωm, and thus providing a gap of 10 μm or above from the radio frequency semiconductor circuit can realize a radio frequency circuit with small unnecessary electromagnetic radiation and high performance.

Preferably, the semiconductor substrate has specific resistance larger than 10 Ωcm. Instead of the gap or in addition thereto, increasing the specific resistance of the semiconductor substrate can also realize a radio frequency circuit chip with small unnecessary electromagnetic radiation and high performance.

A bumpy part may be formed on a surface of the semiconductor substrate facing the radio frequency semiconductor circuit. The unnecessary electromagnetic radiation in the package can be favorably suppressed, realizing a radio frequency circuit chip with high performance.

Specifically, the bumpy part may be formed with a plurality of conical projections arranged at a predetermined interval. Alternatively, the bumpy part may be a rough surface with a surface roughness of 0.1 μm to 10 μm.

An antireflection film preventing reflection of an electric wave discharged from the radio frequency semiconductor circuit may be formed on a surface of the semiconductor substrate facing the radio frequency semiconductor circuit. As a result, the unnecessary electromagnetic radiation in the package can be suppressed effectively, realizing a radio frequency circuit chip with high performance. The “antireflection film” is of a material through which electric waves are transmitted and which is different from an electric wave absorbing body absorbing the electric waves through conversion into heat or otherwise.

A second semiconductor circuit electrically connected to the radio frequency semiconductor circuit may be formed on a surface of the semiconductor substrate facing the radio frequency semiconductor circuit. Typically, the radio frequency semiconductor circuit does not function on its own, and in many cases, is connected to a different semiconductor circuit to be used. Thus, forming onto the semiconductor substrate a second semiconductor circuit (typically a low frequency circuit for signal processing) electrically connected to the radio frequency semiconductor circuit can realize a radio frequency circuit chip with high packaging density. The “second” indicates a semiconductor circuit different from this radio frequency semiconductor circuit, in a case where the radio frequency semiconductor circuit is considered as a first semiconductor circuit.

A semiconductor device according to another aspect of the invention includes: a radio frequency substrate including a radio frequency semiconductor circuit and an antenna electrically connected to the radio frequency semiconductor circuit; a silicon semiconductor substrate including a second semiconductor circuit electrically connected to the radio frequency semiconductor circuit, the silicon semiconductor substrate having a second surface facing a first surface of the radio frequency substrate; and a joining frame arranged between the first and second surfaces, the joining frame joining the radio frequency substrate to the silicon semiconductor substrate.

Typically, the radio frequency semiconductor circuit does not function on its own, and in many cases, is connected to a different semiconductor circuit to be used. Thus, forming onto the silicon substrate a second semiconductor circuit (typically a low frequency circuit for signal processing) electrically connected to the radio frequency semiconductor circuit can realize a radio frequency circuit chip with high packaging density.

The radio frequency semiconductor circuit may be formed on the first surface of the radio frequency substrate, the second semiconductor circuit may be formed on the second surface of the silicon semiconductor substrate, and the radio semiconductor circuit and the second semiconductor circuit may be electrically connected to each other through a connecting post. As a result, favorable connection in radio frequency regions can be realized.

The radio frequency semiconductor circuit and the second semiconductor circuit may be arranged inside an airtight region surrounded by the radio frequency substrate, the silicon semiconductor substrate, and the joining frame. As a result, airtightness is ensured, and a semiconductor device with high performance can be realized.

The radio frequency substrate may further include a wire formed on a surface opposite to the first surface. The radio frequency semiconductor circuit and the wire may be electrically connected to each other through the via hole penetrating through the radio frequency substrate in a thickness direction thereof. As a result, a terminal of the radio frequency semiconductor circuit arranged in the airtight region can be pulled out to outside. A mode of the connection between the radio frequency semiconductor circuit and the wire is not limited to the via hole, but may be achieved by, for example, electromagnetic coupling through, for example, the antenna.

The antenna may be formed on a surface opposite to the first surface of the radio frequency substrate, and the radio frequency semiconductor circuit and the antenna may be electrically connected to each other through the via hole penetrating through the radio frequency substrate. As a result, favorable connection in radio frequency regions can be realized.

The radio frequency semiconductor circuit and the antenna may be arranged not to overlap each other. As a result, a ground can be provided on a rear surface of the radio frequency semiconductor circuit and the antenna, and thus a semiconductor chip having a radio frequency characteristic with high performance can be realized.

The semiconductor device may further include a mounting substrate joined to the surface opposite to the first surface of the radio frequency substrate. The mounting substrate may include a through hole formed at a position facing the antenna. The mounting substrate may have a through hole formed at a position facing the antenna. As a result, antenna transmission and reception characteristics improve.

The antenna may be formed on the first surface and outside of the airtight region. The antenna is exposed outside of the chip, and thus an easy-to-mount semiconductor device having strong noise and high performance can be realized.

The antenna may be formed on the first surface of the radio frequency substrate, a ground may be formed on a surface opposite to the first surface of the radio frequency substrate, and a slot may be formed at a position of the ground overlapping the antenna. As a result, antenna transmission and reception characteristics improve.

The radio frequency semiconductor circuit may be formed on a surface opposite to the first surface of the radio frequency substrate, and molded by a resin member.

The second semiconductor circuit may be formed on the second surface of the silicon semiconductor substrate, and the radio frequency semiconductor circuit and the second semiconductor circuit may be electrically connected to each other through the via hole penetrating through the radio frequency substrate. As a result, favorable connection in radio frequency regions can be realized.

The second semiconductor circuit may be formed on a surface opposite to the second surface of the silicon semiconductor substrate, and the radio frequency semiconductor circuit and the second semiconductor circuit may be electrically connected to each other through a first via hole penetrating through the radio frequency substrate and a second via hole penetrating through the silicon semiconductor substrate. As a result, favorable connection in radio frequency regions can be realized.

The joining frame may be formed by bonding with a bonding member a first joining frame projecting from the first surface of the radio frequency substrate and a second joining frame projecting from the second surface of the silicon semiconductor substrate. As a result, airtightness can be easily ensured at low cost.

The radio frequency substrate may be any of a sapphire substrate, a nitride semiconductor substrate, a GaAs sunbstrate, an SiC substrate, and a silicon semiconductor substrate. Use of these substrates can realize a semiconductor device with a favorable radio frequency characteristic.

A semiconductor device manufacturing method according to another aspect of the invention refers to a method of manufacturing the semiconductor device. Specifically, provided are: forming the radio frequency semiconductor circuit in each of a plurality of regions previously laid out on a principal surface of a first wafer serving as a starting material of the radio frequency substrate; forming, on at least either of the principal surface of the first wafer and a principal surface of a second wafer serving as a starting material of the semiconductor substrate, a joining frame in a manner such as to lay out the plurality of regions; superposing the first wafer and the second wafer on each other in a manner such as to sandwich the joining frame; joining the first and second wafers by partially heating the first and second wafers along the joining frame; and cutting the joined first and second wafers along the joining frame. The joining frame may be formed into a grid-like shape in a manner such as to lay out the plurality of regions.

A semiconductor device manufacturing method according to another aspect of the invention refers to a method of manufacturing the semiconductor device. Specifically, provided are: forming the radio frequency semiconductor circuit and the antenna in each of a previously laid-out plurality of regions of a first wafer serving as a starting material of the radio frequency substrate; forming the second semiconductor circuit in each of a previously laid out plurality of regions of a second wafer serving as a starting material of the silicon semiconductor substrate; forming, at at least either of the first wafer and the second wafer, a joining frame in a manner such as to lay out the plurality of regions; superposing the first wafer and the second wafer on each other in a manner such as to sandwich the joining frame; joining the first and second wafers by partially heating the first and second wafers along the joining frame; and cutting the joined first and second wafers along the joining frame. The joining frame may be formed into a grid-like shape in a manner such as to lay out the plurality of regions.

As described above, not heating all the superposed first and second wafer but partially heating only the joining frame can prevent, for example, breakdown and detachment attributable to a difference in thermal expansion coefficient between the first and second wafers.

The first wafer may be formed of a light-transmissive material, and the first and second wafers may be joined to each other by irradiating laser light along the joining frame from a side of the first wafer. More specifically, the first wafer may be a sapphire substrate. As described above, forming the first wafer with the sapphire substrate (light transmissive material) makes it possible to locally heat only the first and second joining frames.

With the semiconductor device according to the invention, arranging the radio frequency semiconductor circuit in the airtight region laid out by the radio frequency substrate, the semiconductor substrate, and the joining frame can provide a semiconductor device with excellent airtightness and high performance.

Realized with the semiconductor device according to the invention can be a wafer-level, multichip size package semiconductor device which is small, thin, and low-cost, has high performance, and has the radio frequency semiconductor circuit, the antenna, and the silicon integrated circuit integrated.

### FURTHER INFORMATION ABOUT TECHNICAL BACKGROUND TO THIS APPLICATION

The disclosure of Japanese Patent Application No. 2009-038670 filed on Feb. 20, 2009 and Japanese Patent Application No. 2009-038409 filed on Feb. 20, 2009 including specification, drawings and claims is incorporated herein by reference in its entirety.

The disclosure of PCT application No. PCT/JP09/006624 filed on Dec. 4, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a schematic sectional view of a chip size package according to a first embodiment of the present invention;

FIG. 2 is a perspective view of the chip size package according to the first embodiment of the invention;

FIG. 3 is an enlarged perspective view of the periphery of an input and output via hole of the chip size package according to the first embodiment of the invention;

FIG. 4 is a schematic sectional view of a chip size package of a multichip type according to a second embodiment of the invention;

FIG. 5 is a view illustrating a process of superimposing individually manufactured first and second wafers on each other in chip size package manufacturing processes according to embodiments of the invention;

FIG. 6 is a view illustrating a process of locally heating the superimposed first and second wafers in the chip size package manufacturing processes according to the embodiments of the invention;

FIG. 7 is a view illustrating a process of dicing the joined first and second wafers in the chip size package manufacturing processes according to the embodiments of the invention;

FIG. 8 is a graph showing attenuation characteristics (S21) of the chip size package according to the embodiments of the invention;

FIG. 9 is a schematic sectional view of the chip size package according to the third embodiment of the invention;

FIG. 10 is a perspective view of the chip size package according to the third embodiment of the invention;

FIG. 11 is a schematic sectional view of the chip size package according to the fourth embodiment of the invention;

FIG. 12 is a schematic sectional view of the chip size package according to the fifth embodiment of the invention;

FIG. 13 is a schematic sectional view of the chip size package according to the sixth embodiment of the invention;

FIG. 14 is a schematic sectional view of the chip size package according to the seventh embodiment of the invention;

FIG. 15 is a view illustrating a process of superimposing individually manufactured first and second wafers on each other in chip size package manufacturing processes according to the embodiments of the invention;

FIG. 16 is a view illustrating a process of locally heating the superimposed first and second wafers in the chip size package manufacturing processes according to the embodiments of the invention;

FIG. 17 is a view illustrating a process of dicing the joined first and second wafers in the chip size package manufacturing processes according to the embodiments of the invention;

FIG. 18 is a block diagram of a wireless transmitting and receiving device as one example of application of the chip size package according to the embodiments of the invention;

FIG. 19 is a block diagram of a laser device as another example of the application of the chip size package according to the embodiments of the invention; and

FIG. 20 is a sectional view of a conventional wafer-level package.

### DESCRIPTION OF THE PREFERRED EMBODIMENT(S)

### First Embodiment

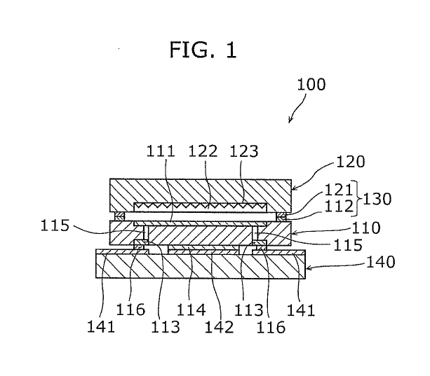

Hereinafter, a chip size package 100 according to a first embodiment of the present invention will be described with reference to FIGS. 1 to 3. First, FIG. 1 is a sectional view showing a state in which the chip size package (semiconductor device) 100 according to the first embodiment is mounted in a mounting substrate 140.

As shown in FIG. 1, the chip size package 100 includes: a radio frequency substrate 110; a semiconductor cover substrate (also referred to as “semiconductor substrate, and the same applies below) 120; and a joining frame 130 joining the radio frequency substrate 110 to the semiconductor cover substrate 120. This chip size package 100 is mounted on the mounting substrate 140 as a printed substrate.

The radio frequency substrate 110 according to the first embodiment is a sapphire substrate. Formed on a principal surface (top surface in FIG. 1) of the radio frequency substrate 110 are: a nitride semiconductor layer on which a radio frequency semiconductor circuit 111 (monolithic microwave integrated circuit: MMIC) is formed; and a first joining frame 112 projecting in a manner such as to surround the radio frequency semiconductor circuit 111. Formed on a surface (bottom surface in FIG. 1) opposite to the principal surface are: wires 113 and a ground 114. The radio frequency semiconductor circuit 111 and the wires 113 are electrically connected to each other through via holes 115 penetrating through the radio frequency substrate 110 in a thickness direction (vertical direction in FIG. 1) thereof.

The “radio frequency” in this specification indicates, for example, a frequency band of 1 GHz or above. The “radio frequency semiconductor circuit” indicates the one which is connected to, for example, an antenna and functions as a wireless transmitting and receiving device, an on-vehicle laser, or the like. The “principal surface” in this specification indicates the surface of the radio frequency substrate 110 facing the semiconductor cover substrate 120, and the surface of the semiconductor cover substrate 120 facing the radio frequency substrate 110 (the same applies to the embodiments below).

The radio frequency semiconductor circuit 111 is formed of, for example, a GaN semiconductor deposited on the principal surface of the sapphire substrate as the chip size package 100 through epitaxial growth. Input and output and bias terminals of the radio frequency semiconductor circuit 111 are pulled out from a rear surface of the radio frequency substrate 110 through via holes 115 for pulling out terminals to the outside. Each of the terminals is connected to a wire 141 on the mounting substrate 140 through, for example, a bump 116 formed on the rear surface of the radio frequency substrate 110 (chip). Formed at a position overlapping the radio frequency semiconductor circuit 111 on the surface opposite to the principal surface of the radio frequency substrate 110 is a ground 114, which is in common with a ground 142 of the mounting substrate 140.

The semiconductor cover substrate 120 according to the first embodiment is a silicon substrate. Formed on a principal surface (bottom surface in FIG. 1) of the semiconductor cover substrate 120 facing the radio frequency substrate 110 are: a second joining frame 121 projecting from an outer edge part; and a concave part 122 located at a position facing the radio frequency semiconductor circuit 111. Formed on a bottom wall of the concave part 122 is an antireflection structure 123.

The joining frame 130 joining the radio frequency substrate 110 (chip) and the semiconductor cover substrate 120 is formed by joining together the first joining frame 112 formed at the radio frequency substrate 110 and the second joining frame 121 formed at the semiconductor cover substrate 120 in a manner such as to surround the radio frequency semiconductor circuit 111 (MMIC) and the via holes 115. A region surrounded by the radio frequency substrate 110, the semiconductor cover substrate 120, and the joining frame 130 serves as an airtight region.

The first and second joining frames 112 and 121 are each formed of metal such as gold or copper plating. The first and second joining frames 112 and 121 are joined to each other by a soldering agent (bonding member) such as gold tin (Au/Sn). Forming the airtight region with the joining frame 130 and arranging the radio frequency semiconductor circuit 111 within this airtight region can provide high reliability of the radio frequency semiconductor circuit 111.

In the chip size package 100 of the first embodiment, a hollow space is formed between the radio frequency substrate 110 (chip) and the semiconductor cover substrate 120 by the joining frame 130 and the concave part 122 of the semiconductor cover substrate 120. A silicon semiconductor is generally electrically-conductive, and thus has great dielectric loss, resulting in loss in radio frequency regions. Thus, provided in present invention is the hollow space inside of the semiconductor cover substrate 120 formed of silicon, that is, an appropriate hollow space above the radio frequency semiconductor circuit 111 and between the radio frequency semiconductor circuit 111 and the semiconductor cover substrate 120. This provides design such that the semiconductor cover substrate 120 does not have any influence (for example, characteristic deterioration) on the radio frequency semiconductor circuit 111.

Generally, when a cover is placed on a radio frequency semiconductor, unnecessary electromagnetic radiation is reflected on the cover, leading to characteristic deterioration of the radio frequency semiconductor circuit 111. However, in the present invention, the unnecessary electromagnetic waves are gradually attenuated inside the semiconductor cover substrate 120, which can therefore suppress the unnecessary electromagnetic radiation without causing the reflection.

Moreover, providing the antireflection structure 123 on the bottom wall of the concave part 122 of the semiconductor cover substrate 120 makes it possible to suppress electromagnetic wave reflection on a front surface of the semiconductor cover substrate 120. Provided as a detailed structure of the antireflection structure 123 may be a plurality of conical projections which project from the bottom wall of the concave part 122 and which are arranged at predetermined intervals, or a rough surface having greater surface roughness (a maximum height of 0.1 μm to 10 μm) than that of other portions of the bottom wall. As still another embodiment of the antireflection structure 123, the bottom wall of the concave part 122 can have a photonic crystal structure.

Alternatively, instead of the antireflection structure 123, an antireflection film may be formed. The antireflection film has a flattened structure, and is formed of a material, for example, Sin different from a material of the silicon semiconductor. Furthermore, the bottom wall and side walls of the concave part 122 may be coated with gold.

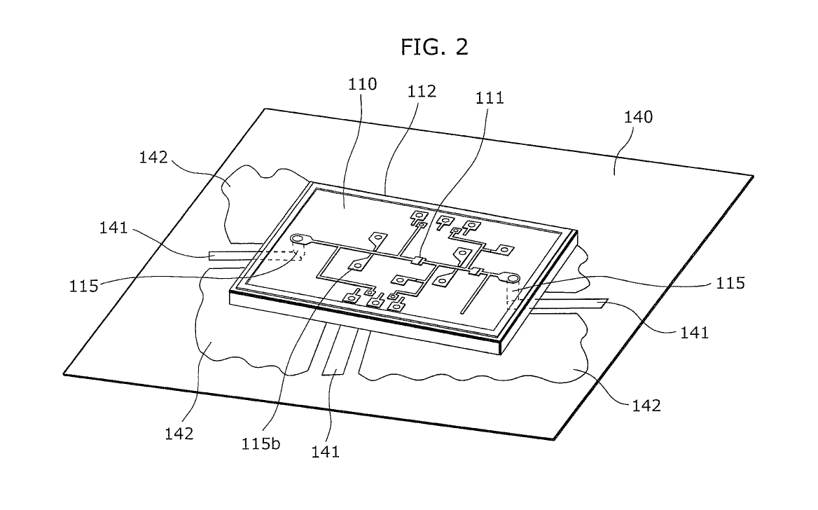

FIG. 2 is a perspective view showing a package inner structure in a state in which the chip size package 100 with the semiconductor cover substrate 120 removed is mounted on the mounting substrate 140.

Formed on the principal surface of the radio frequency substrate 110 (chip) is the radio frequency semiconductor circuit 111 (MMIC) formed with a microstrip wiring structure. Input and output wires of the radio frequency semiconductor circuit 111 are connected to the wires 141 on the mounting substrate 140 through the via holes 115 for inputting and outputting. A ground on the radio frequency semiconductor circuit 111 (not shown in FIG. 1) and the ground 114 on the rear surface of the radio frequency substrate 110 are connected to each other with a via hole 115b for grounding (not shown in FIG. 1). The wires of the radio frequency semiconductor circuit 111 has a microstrip wiring structure, and on the rear surface of the radio frequency substrate 110 (chip), metal is placed as a ground. In the first embodiment, the ground 114 of the radio frequency substrate 110 (chip) and the ground 142 on a front surface of the mounting substrate 140 where the chip size package 100 is mounted are in common with each other. Thus, for the semiconductor circuit, the grounds that are very stable for high frequencies can be provided, exerting a radio frequency characteristic with high performance.

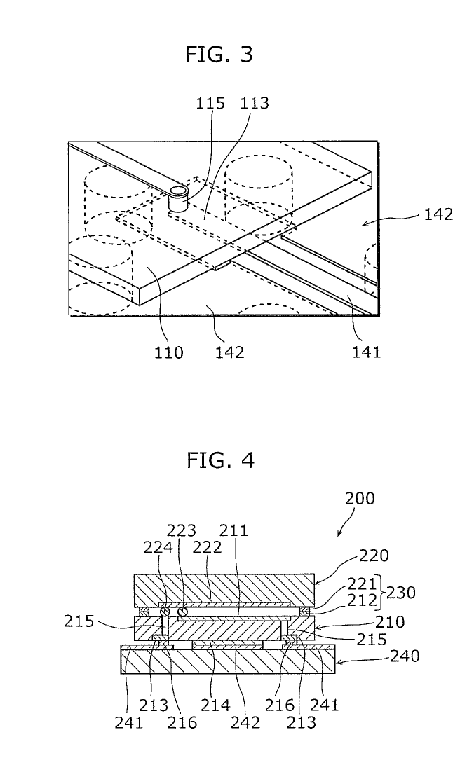

FIG. 3 is an enlarged perspective view of a peripheral part of the via hole 115 for inputting and outputting of the chip size package 100 according to the first embodiment. The radio frequency substrate 110 (chip) is mounted on the mounting substrate 140. The input and output wires of the radio frequency semiconductor circuit 111 (MMIC) are connected to the wires 113 on the rear surface of the radio frequency substrate 110 (chip) through the via holes 115 for inputting and outputting.

The sapphire substrate as the radio frequency substrate 110 is an insulating substrate. Thus, metal in the via holes 115 provides electrical connection between the principal and bottom surfaces of the radio frequency substrate 110. A connection structure provided by the via holes 115 provides a very short distance between the radio frequency semiconductor circuit 111 and the mounting substrate 140, thus permitting minimum connection loss to be achieved. Further, adoption of the sapphire substrate with low dielectric loss permits formation of the via holes 115 for inputting and outputting having an excellent radio frequency characteristic. Note that the wire 113 on the rear surface of the radio frequency substrate 110 (chip) and the wire 141 on the mounting substrate 140 are in common with each other.

The wires of the radio frequency semiconductor circuit 111 have the microstrip wiring structure, and the ground 114 of metal is formed on the rear surface of the radio frequency substrate 110 (chip). The metal at part of the ground 114 on this rear surface is removed. Such a ground pattern permits adjustment of the connection loss of the via holes 115 for inputting and outputting and a connection impedance characteristic. As a result, a structure having a favorable connection characteristic in radio frequency regions can be designed. It is preferable that a portion where the metal has been removed, that is, a distance between the ground 114 of metal and the via holes 115 be between 0.01 μm to 0.20 μm.

The wires 113 on the rear surface of the radio frequency substrate 110 (chip) and the wires 141 on the mounting substrate 140 have a coplanar wiring structure where the grounds 114 and 142 are formed on both sides of the wires 113 and 141. A gap width of the coplanar wires on the chip rear surface is influenced by dielectric constants of a material of the mounting substrate 140 and a material of the radio frequency substrate 110. Thus, with consideration given such that the two types of wires 113 and 141 have equal impedance, the gap width of the coplanar wires on the chip rear surface is set wider than a gap width of the coplanar wires on the mounting substrate 140. Adjustment can also be made to provide a favorable impedance characteristic by providing condition in which the wire width or both the wire width and the gap width of the wires 113 on the rear surface of the radio frequency substrate 110 are different from a wire width and the gap width of the wires on the mounting substrate 140.

Here, the structure of the wires 141 on the mounting substrate 140 is the coplanar wiring structure or a grounded coplanar wiring structure, but the wires 114 on the mounting substrate 140 may have a microstrip wiring structure. Similarly, the input and output wires of the radio frequency semiconductor circuit 111 and the wires of the radio frequency semiconductor circuit 111 may have a coplanar wiring structure or a ground coplanar wiring structure.

Next, referring to FIG. 4, a chip size package 200 of a multichip type according to a second embodiment of the invention will be described. FIG. 4 is a sectional view of the chip size package 200 according to the second embodiment.

Most of radio frequency semiconductor circuit chips such as a GaN semiconductor do not operate as a system on their own. Thus, they needs to be connected to an LSI chip for signal processing formed of a silicon semiconductor. Thus, the chip size package 200 according to the second embodiment is formed by integrating a radio frequency semiconductor circuit 211 and a silicon integrated circuit (also referred to as “second semiconductor circuit, the same applies below) 222 that performs signal processing, etc. FIG. 4 is a view showing a state in which the chip size package 200 is mounted on a mounting substrate 240.

As shown in FIG. 4, the chip size package 200 according to the second embodiment of the invention has a radio frequency substrate 210 and a semiconductor cover substrate 220 joined to each other with a joining frame 230 in between.

The radio frequency substrate 210 is a sapphire substrate. Formed on a principal surface of the radio frequency substrate 210 are: the radio frequency semiconductor circuit 211 (monolithic microwave integrated circuit: MMIC); and a first joining frame 212. Formed on a surface opposite to the principal surface are: wires 213 and a ground 214. Further provided are two via holes 215 (on the right in FIG. 4) penetrating through the radio frequency substrate 210 in a thickness direction thereof. The radio frequency semiconductor circuit 211 is connected to a wire 241 (on the right in FIG. 4) of the mounting substrate 240 through one of the via holes 215 (on the right in FIG. 4). To a tip of this wire 241, an antenna or the like is fitted.

The semiconductor cover substrate 220 has, formed on its principal surface facing the radio frequency substrate 210, a second joining frame 221 and the silicon integrated circuit 222. The radio frequency semiconductor circuit 211 and the silicon integrated circuit 222 are placed in a manner such as to face each other. The silicon integrated circuit 222 is electrically connected through a connecting post 223 of metal formed between the radio frequency substrate 210 and the semiconductor cover substrate 220. A signal terminal and a bias terminal of the silicon integrated circuit 222 are pulled out of the chip through a connecting post 224 and the via hole 215 on the other side (on the left in FIG. 4) formed in the radio frequency substrate 210, and is further connected to the wire 241 on the mounting substrate 240 through a bump 216 or the like formed on a rear surface of the radio frequency substrate 210 (chip).

A region laid out by the radio frequency substrate 210 (chip), the semiconductor cover substrate 220, and the joining frame 230 serves as an airtight region. This airtight region seals the radio frequency semiconductor circuit 211 (MMIC), the silicon integrated circuit 222, and the via hole 215 for the terminal pull-out.

In FIG. 4 describing the second embodiment, the connecting post 224 and the via holes 215 in the radio frequency substrate 210 can also be used for ground connection. Furthermore, a GaN terminal may also be pulled out of the chip through the via hole 215 in the radio frequency substrate 210 (chip). The electrical connection between the radio frequency semiconductor circuit 211 and the silicon integrated circuit 222 has been described, referring to a structure using the connecting post 223, but the connection may also be achieved by electromagnetic coupling using an antenna or the like. In the second embodiment, a concave part is not provided at the semiconductor cover substrate 220, but a height of the joining frame 230 may be adjusted to form a predetermined hollow space (gap) between the radio frequency semiconductor circuit 211 and the semiconductor cover substrate 220.

### Manufacturing Method of the Embodiment

Generally, for a chip size package, wafer-level packaging is very useful in terms of cost. Used for a wafer-level packaging method are a wafer gluing device and a technology therefor. Specifically, a radio frequency semiconductor wafer in a wafer state is glued to a silicon wafer substrate, and then the glued substrates are diced (cut out) into a chip size, thereby completing the packaging.

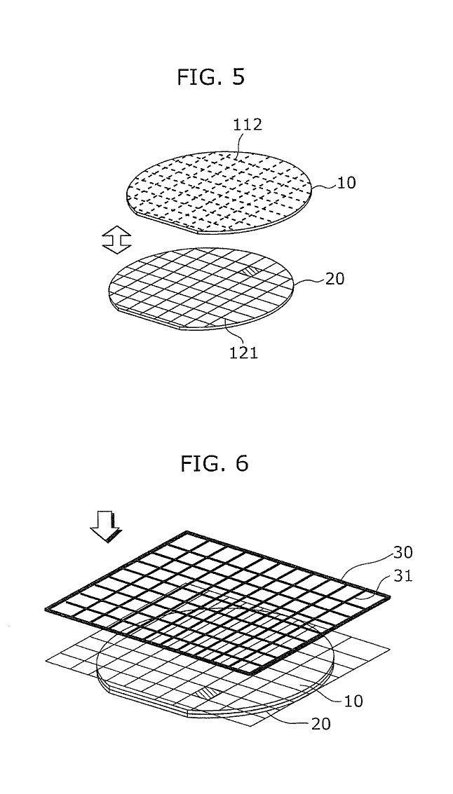

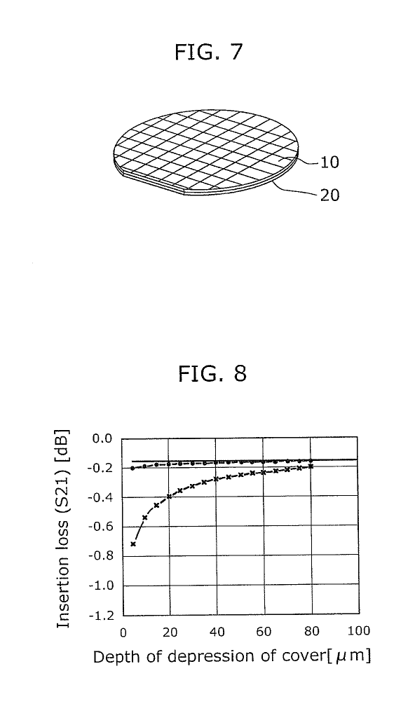

Also in the embodiments of the invention, the wafer-level packaging is similarly possible. Referring to FIGS. 5 to 7, processes of manufacturing the chip size package 100 according to the first embodiment will be described. FIG. 5 is a view showing a state before first and second wafers 10 and 20 are glued to each other. FIG. 6 is a view showing the process of partially heating the first and second wafers 10 and 20 to join the both to each other. FIG. 7 is a view showing the process of dicing the joined first and second wafers 10 and 20.

Conventionally, in a case where substrates, such as a sapphire substrate and a silicon substrate, having greatly different thermal expansion coefficients are glued to each other, due to thermal expansion caused by heating and cooling in a joining process, wafer pulverization, reseparation, etc. occur, resulting in failure to achieve the gluing. Thus, with the manufacturing method of this embodiment, the method of partially heating only a wafer joined surface is used to reduce the amount of thermal expansion, achieving favorable gluing. The amount of thermal expansion can be calculated by multiplying the thermal expansion coefficients of the materials by areas and flash temperatures of the materials.

In the manufacturing processes in this embodiment, as shown in FIG. 5, the first wafer 10 as a starting material of the radio frequency substrate 110 and the second wafer 20 as a starting material of the semiconductor cover substrate 120 are first formed independently from each other.

Specifically, formed at the first wafer 10 is the grid-like first joining frame 112 projecting from the principal surface (bottom surface in FIG. 5). For each of a plurality of regions divided by the grid-like first joining frame 112, the radio frequency semiconductor circuit 111 is formed on the principal surface, the wires 113 and the ground 114 are formed on the rear surface, and the via holes 115 are formed inside. Similarly, formed at the second wafer 20 is the grid-like second joining frame 121 projecting from the principal surface (top surface in FIG. 5). For each of a plurality of regions divided by the grid-like second joining frame 122, the concave part 122 and the antireflection structure 123 are formed on the principal surface. Next, as shown in FIG. 6, the first and second wafers 10 and 20 are superposed on each other in a manner such that the first and second joining frames 112 and 121 face each other with the bonding member (not shown in the figure) in between. At this point, they are superposed on each other in a manner such that the first wafer 10 formed of a light-transmissive material (sapphire) is located at the top.

Next, by using a light-blocking mask 30, the first and second wafers 10 and 20 superposed on each other are irradiated with a laser. This light-blocking mask 30 is provided with grid-like slits corresponding to the first and second joining frames 112 and 121 superposed on each other, and thus the laser is selectively irradiated to the first and second joining frames 112 and 121. Used here for laser light can be any laser that radiates light of wavelengths ranging from 10 nm to 1 μm.

Through the laser irradiation, temperatures of the first and second joining frames 112 and 121 rise, whereby the bonding member between the first and second joining frames 112 and 121 melts. Then when this bonding member is solidified again, the first wafer 10 and the second wafer 20 are joined to each other.

Next, as shown in FIG. 7, the joined first and second wafers 10 and 20 are diced along the first and second joining frames 112 and 121 whereby the chip size package 100 can be cut out.

Alternatively, laser dicing can be performed in state in which the first and second wafers 10 and 20 are superposed on each other, and the first and second joining frames 112 and 121 can be heated with heat generated through the laser dicing to thereby achieve the joining. The description refers to the method of performing the partial laser irradiation by using the light-blocking mask 30, but with a spot of laser light focused, an irradiation position of the laser light can be operated and moved to thereby partially heat the joined part. Similarly, a wafer position can also be operated and moved. Furthermore, as the partial heating method, use of the laser irradiation has been described, but it can also be realized by a method of placing at a top, a bottom, or both parts of the wafers grid-like metal having substantially the same shape as that of the joined part of the semiconductor chip and then heating this grid-like metal.

Illustrated as examples of the first and second joining frames 112 and 121 in the aforementioned embodiment are those which have straight sides forming the grid, but they are not limited thereto, and thus the adjacent sides are not necessarily strictly parallel to each other and, for example, may snake their way.

Illustrated in the aforementioned embodiments is an example in which the first joining frame 112 is formed at the first wafer 10 and the second joining frame 121 is formed at the second wafer 20, but a joining frame may be provided at least one of the first and second wafers 10 and 20 and the first and second wafers 10 and 20 may be superposed on each other in a manner such as to sandwich this joining frame.

Furthermore, the method of manufacturing the chip size package 100 according to the first embodiment has been described, and it is needless to say that the chip size package 200 can also be manufactured by the same method by changing positions, numbers, etc. of semiconductor circuits, wires, grounds, via holes, etc. formed at the first and second wafers 10 and 20.

Next, referring to FIG. 8, attenuation characteristics (S21) of the chip size package 100 according to the first embodiment of the invention will be described. FIG. 8 shows: the attenuation characteristic (expressed by a straight line in FIG. 8) of the radio frequency semiconductor circuit 111 in a case where the semiconductor cover substrate 120 is removed; the attenuation characteristic (expressed by • in FIG. 8) of the radio frequency semiconductor circuit 111 in a case where specific resistance (or electric resistivity) of the semiconductor cover substrate 120 is 1000 Ωm; and the attenuation characteristic (expressed by × in FIG. 8) of the radio frequency semiconductor circuit 111 in a case where the specific resistance of the semiconductor cover substrate 120 is 10 Ωcm. The experiment was performed, with a distance (hereinafter referred to as “space quantity”) between the radio frequency semiconductor circuit 111 and the semiconductor cover substrate 120 changed from 0 μm to 80 μm.

In the case where the semiconductor cover substrate 120 was removed, the attenuation characteristic turned to −0.18 [dB].

Next, in the case where the specific resistance of the semiconductor cover substrate 120 is 1000 Ωm, compared to the case where the semiconductor cover substrate 120 was removed, the attenuation characteristic slightly deteriorated in a range where the space quantity is less than 20 μm. However, the attenuation characteristic in a range higher than the aforementioned range (20 μm) is substantially equal to that in the case where the semiconductor cover substrate 120 was removed.

Next, in the case where the specific resistance of the semiconductor cover substrate 120 is 10 Ωm, compared to the case where the semiconductor cover substrate 120 was removed, the attenuation characteristic greatly deteriorated in the range where the space quantity is less than 20 μm. However, as the space quantity increased, the attenuation characteristic improved.

Moreover, although not shown in the figure, it was found that in a case where the side and bottom walls of the concave part 122 are coated with gold, the attenuation characteristic greatly deteriorated in a range where the space quantity is less than 10 μm, but as the space quantity increased, the attenuation characteristic greatly improved. The aforementioned results verify that it is preferable that the specific resistance of the semiconductor cover substrate 120 be high, which is thought to be because a member with a high dielectric constant hardly influences the attenuation characteristic of the radio frequency semiconductor circuit 111. Moreover, it was found that it is preferable that the space quantity be large, which is thought to be because a member arranged at a position distant from the radio frequency semiconductor circuit 111 hardly influences the attenuation characteristic.

General specific resistance of the semiconductor cover substrate 120 is 10 Ωcm. Thus, it is preferable to ensure at least 10 μm for the space quantity. It is more preferable to ensure 20 μm or above, and even more preferable to ensure 50 μm or above. It is needless to say that the aforementioned results are applicable to not only the first embodiment but also the chip size package 200 according to the second embodiment.

### [Supplementary Description]

The radio frequency semiconductor circuit and its wires form the microstrip wiring structure but they may form a coplanar wiring structure. The radio frequency semiconductor circuit is provided as the GaN semiconductor but may be any other semiconductor such as a silicon semiconductor. It has been described that the substrate of the GaN semiconductor as the radio frequency semiconductor circuit is a sapphire substrate, but it may be of any other material such as SiC or Si. It has been described that the semiconductor cover substrate is a silicon semiconductor substrate, but may be any other electrically-conductive substrate.

It has been described that the semiconductor cover substrate is a substrate formed with a dint, but no dint may be formed or the antireflection structure may not be formed in the substrate. It has been described that positions of the via holes and the connecting posts are on a radio frequency semiconductor circuit side located inwardly of the joining frame, but they may be located inside of the joining frame.

### Third Embodiment

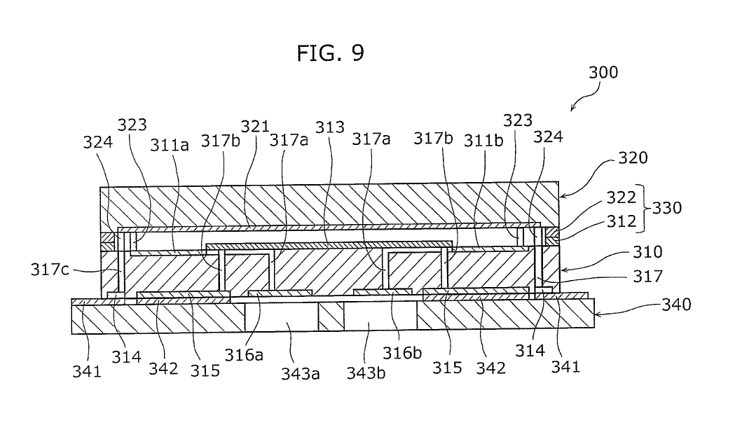

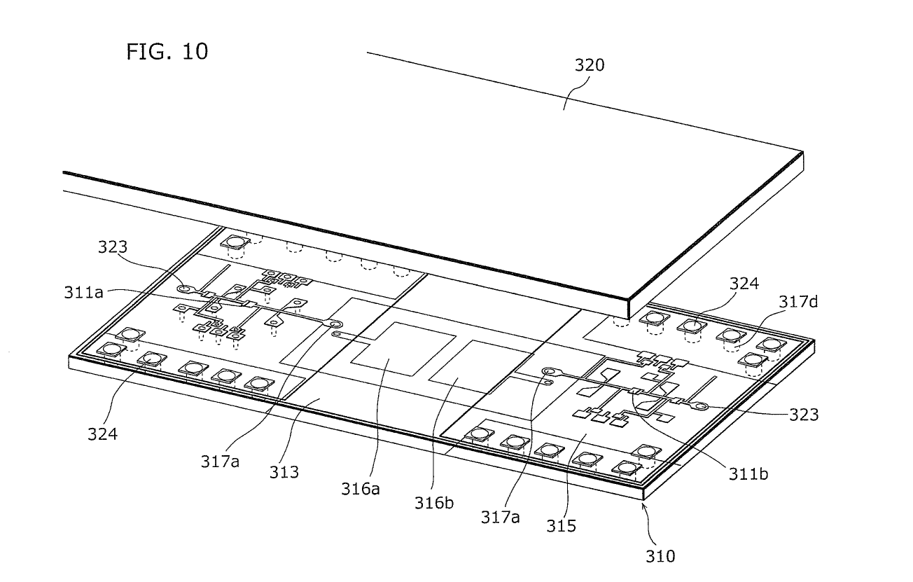

Hereinafter, a chip size package 300 according to the third embodiment of the invention will be described with reference to FIGS. 9 and 10. First, FIG. 9 is a sectional view showing a state in which the chip size package (semiconductor device) 300 according to the third embodiment is mounted on a mounting substrate 340 as a printed substrate.

As shown in FIG. 9, the chip size package 300 is composed of: a radio frequency substrate 310; a semiconductor cover substrate 320, and a joining frame 330 joining the radio frequency substrate 310 and the semiconductor cover substrate 320 to each other. The chip size package 300 is mounted on the mounting substrate 340 as the printed substrate.

The radio frequency substrate 310 according to the third embodiment is a sapphire substrate. Formed on a principal surface (top surface in FIG. 9) of the radio frequency substrate 310 are: a nitride semiconductor layer on which radio frequency semiconductor circuits 311a and 311b (monolithic microwave integrated circuits: MMICs) are formed; a first joining frame 312 projecting in a manner such as to surround the radio frequency semiconductor circuits 311a and 311b; and a ground 313. Formed on a surface (bottom surface in FIG. 9) opposite to the principal surface are: wires 314, grounds 315, and two antennas 316a and 316b.

Formed in the radio frequency substrate 310 are: via holes 317a for antennas which penetrate through the radio frequency substrate 310 in a thickness direction (vertical direction in FIG. 9) thereof and which electrically connect the radio frequency semiconductor circuits 311a and 311b and the antennas 316a and 316b to each other; via holes 317b for grounds which connects the ground 313 and the grounds 315 to each other; and via holes 317c for terminal pull-out which connect the wires 314 and a silicon integrated circuit 321, to be described below, to each other.

The “radio frequency” in this specification indicates, for example, a frequency band of 1 GHz or above. The “radio frequency semiconductor circuit” indicates the one which is connected to, for example, an antenna and functions as a wireless transmitting and receiving device, an on-vehicle laser, or the like. The “principal surface” in this specification indicates a surface of the radio frequency substrate 310 facing the semiconductor cover substrate 320, and a surface of the semiconductor cover substrate 320 facing the radio frequency substrate 310 (the same applies to the embodiments below).

The radio frequency substrate 310 according to the third embodiment is a silicon substrate. Formed on the principal surface (bottom surface in FIG. 9) of the semiconductor cover substrate 320 facing the radio frequency substrate 310 are: the silicon integrated circuit 321; and a joining frame 322 projecting in a manner such as to surround the silicon integrated circuit 321. The radio frequency semiconductor circuits 311a and 311b and the silicon integrated circuit 321 are electrically connected to each other through connecting posts 323 of metal formed between the radio frequency substrate 310 and the semiconductor cover substrate 320. A signal terminal and a bias terminal of the silicon integrated circuit 321 are pulled out of the chip through connecting posts 324 of metal and the via holes 317 for terminal pull-out formed in the radio frequency substrate 310, and connected to wires 341 on the mounting substrate 340 through bumps (not shown in the figure) formed on a rear surface of the radio frequency substrate 310 (chip).

The joining frame 330 joining the radio frequency substrate 310 (chip) and the semiconductor cover substrate 320 to each other is formed by joining together the first joining frame 312 formed at the radio frequency substrate 310 and the second joining frame 322 formed at the semiconductor cover substrate 320 in a manner such as to surround the radio frequency semiconductor circuits 311a and 311b (MMICs), the silicon integrated circuit 321, the via holes 317c for the terminal pull-out, etc. A region surrounded by the radio frequency substrate 310, the semiconductor cover substrate 320, and the joining frame 330 serves as an airtight region.

The first and second joining frames 312 and 322 are each formed of metal such as gold or copper plating. The first and second joining frames 312 and 322 are joined to each other by a soldering agent (bonding member) such as gold tin (Au/Sn). Forming the airtight region with the joining frame 330 and arranging the radio frequency semiconductor circuits 311a and 311b and the silicon integrated circuit 321 within this airtight region can provide high reliability of the radio frequency semiconductor circuit 311.

The mounting substrate 340 has the wires 341 and grounds 342 formed on a principal surface (top surface in FIG. 9) thereof. Formed at positions facing the antennas 316a and 316b are through holes 343a and 343b, respectively, penetrating through the mounting substrate 340 in a thickness direction thereof.

The radio frequency semiconductor circuit 311a according to the third embodiment is an integrated circuit for a transmission system, such as a power amplifier (PA). On the other hand, the radio frequency semiconductor circuit 311b is an integrated circuit for a reception system, such as a low noise amplifier (LNA). The radio frequency semiconductor circuits 311a and 311b are respectively connected through the via holes 317a to the antenna 316a for transmission and the antenna 316b for reception which are formed on the surface opposite to the principal surface.

The chip size package 300 of the invention radiates electric waves in a direction from the radio frequency semiconductor circuit 311b toward the mounting substrate 340 through the antenna 316a. The chip size package 300 receives electric waves from the mounting substrate 340 through the antenna 316b. Thus, part of the mounting substrate 340 is removed (that is, the through holes 343a and 343b are provided).

The radio frequency semiconductor circuits 311a and 311b provided on the top surface of the radio frequency substrate 310 and the antennas 316a and 316b provided on the rear surface of the radio frequency substrate 310 are arranged in positional relationship where they do not overlap each other. The grounds 315 formed on the rear surface of the radio frequency substrate 310 and the grounds 342 of the mounting substrate 340 are in common with each other.

FIG. 10 is a perspective view showing a package inner structure of the chip size package 300 according to the third embodiment of the invention mounted on the mounting substrate 340 with the semiconductor cover substrate 320 removed.

Formed on the principal surface of the radio frequency substrate 310 (chip) are the radio frequency semiconductor circuits 311a and 311b (MMICs) which are formed with a microstrip wiring structure and which are formed within the joining frame 312. The rear surface of the radio frequency substrate 310 (chip) serves as the grounds 315 formed of metal. In the third embodiment, the grounds 315 provided on the rear surface of the radio frequency substrate 310 (chip) for the radio frequency semiconductor circuits 311a and 311b and the grounds 343 on the mounting substrate 340 where the chip size package 300 is mounted are in common with each other. Thus, the grounds that are very stable for high frequencies can be provided, exerting a radio frequency characteristic with high performance.

One of input and output signal lines of the radio frequency semiconductor circuit 311a is connected through the via hole 317a for the antenna to the antenna 316a formed on the rear surface of the radio frequency substrate 310. Formed at the other one of the input and output signal lines of the radio frequency semiconductor circuit 311a is the connecting post 323, through which the radio frequency semiconductor circuit 311a is electrically connected to the silicon integrated circuit 321 formed at the semiconductor cover substrate 320. The bias terminal of the radio frequency semiconductor circuit 311a is also electrically connected to the silicon integrated circuit 321 through the connecting post 323. The same applies to the radio frequency semiconductor circuit 311b and thus a description thereof is omitted here.

Formed at the radio frequency substrate 310 is a via hole 317d (not shown in FIG. 9) for the bias terminal. The via hole 317d provides electrical connection between a front surface and a rear surface of the radio frequency semiconductor circuits 311a and 311b. Through this via hole 317d, the bias terminals and the signal terminal of the circuits can be pulled out from the rear surface of the radio frequency semiconductor circuits 311a and 311b to be connected to the wires 341 on the mounting substrate 340. Also possible is a mode in which the bias terminals and the signal terminals for, for example, inputting and outputting of the radio frequency semiconductor circuits 311a and 311b are pulled out directly to the rear surface of the radio frequency substrate 310 through the via holes 317d.

### Fourth Embodiment

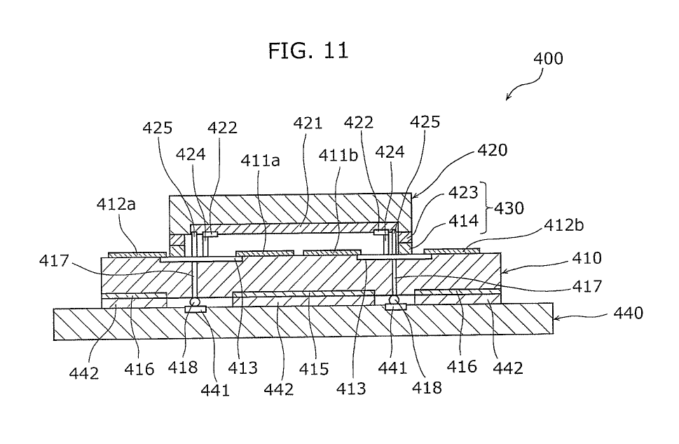

Referring to FIG. 11, a chip size package 400 according to the fourth embodiment of the invention will be described. FIG. 11 is a schematic sectional view of the chip size package 400 mounted on a mounting substrate 440.

A radio frequency substrate 410 is a sapphire substrate. Formed on a principal surface (top surface in FIG. 11) of the radio frequency substrate 410 are: radio frequency semiconductor circuits 411a and 411b; antennas 412a and 412b for transmission and reception; wires 413 electrically connecting the radio frequency semiconductor circuits 411a and 411b and the antennas 412a and 412b to each other; and a first joining frame 414 projecting from the principal surface. Formed on a surface opposite to the principal surface of the radio frequency substrate 410 are: a ground 415 for the radio frequency semiconductor circuits 411a and 411b; and grounds 416 for the antennas 412a and 412b. Further formed at the radio frequency substrate 410 are via holes 417 penetrating through the radio frequency substrate 410 in a thickness direction thereof.

A semiconductor cover substrate 420 is a silicon substrate. Formed on a principal surface (bottom surface in FIG. 11) thereof are: a silicon integrated circuit 421; wires 422 electrically connected to the silicon integrated circuit 421; and a second joining frame 423 projecting from the principal surface.

The wires 413 at the radio frequency substrate 410 and the wires 422 at the semiconductor cover substrate 420 are electrically connected to each other through connecting posts 424. That is, the radio frequency semiconductor circuits 411a and 411b and the silicon integrated circuit 421 are electrically connected to each other.

The silicon integrated circuit 421 is also electrically connected to wires (not shown in the figure) on a rear surface of the radio frequency substrate 410 through the via holes 417 in the radio frequency substrate 410. A bias terminal and a signal terminal of the silicon integrated circuit 421 are connected to wires 441 on the mounting substrate 440 outside through bumps 418 or the like on the rear surface of the radio frequency substrate 410.

The grounds 415 and 416 on the rear surface of the radio frequency substrate 410 and grounds 442 on a front surface of the mounting substrate 440 are commonalized through electrical connection. As a result, the very stable grounds can be provided.

The joining frame 430 is composed of: a first joining frame 414 formed at the radio frequency substrate 410; and a second joining frame 423 formed at the semiconductor cover substrate 420. A region surrounded by the radio frequency substrate 410, the semiconductor cover substrate 420, and the joining frame 430 serves as an airtight region.

In the fourth embodiment, the radio frequency semiconductor circuits 411a and 411b and the silicon integrated circuit 421 are arranged in the airtight region, and the antennas 412a and 412b are arranged outside of the airtight region. This permits transmission and reception performed by the antennas 412a and 412b without providing the through holes 343a and 343b in the mounting substrate 340 which is practiced in the third embodiment. In this fourth embodiment, to keep airtightness of the radio frequency semiconductor circuits 411a and 411b, the connection between the antennas 412a and 412b and the radio frequency semiconductor circuits 411a and 411b may be made through via holes (not shown in the figure) in the radio frequency substrate 410. Specifically, input and output wires from the radio frequency semiconductor circuits 411a and 411b are connected to the wires on the rear surface of the radio frequency substrate 410 through vial holes (not shown in the figure) formed in the joining frame 430. Then the wires on the rear surface are connected to the antennas 412a and 412b through via holes on an outer side of the joining frame 430 in the radio frequency substrate 410.

### Fifth Embodiment

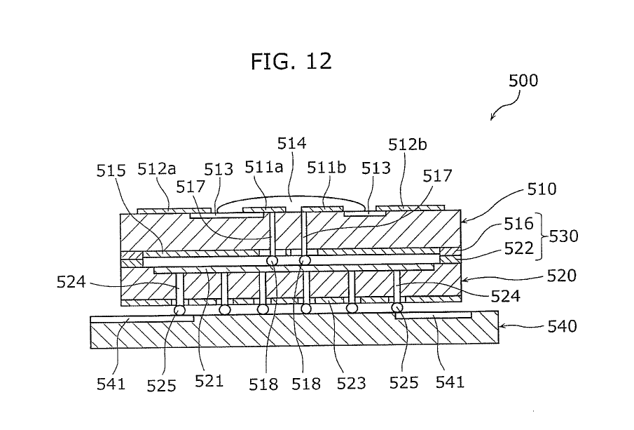

Referring to FIG. 12, a chip size package 500 according to the fifth embodiment of the invention will be described. FIG. 12 is a schematic sectional view of the chip size package 500 mounted on a mounting substrate 540.

A radio frequency substrate 510 is a sapphire substrate. Formed on a surface opposite to a principal surface (top surface in FIG. 12) of the radio frequency substrate 510 are: radio frequency semiconductor circuits 511a and 511b; antennas 512a and 512b for transmission and reception; and wires 513 electrically connecting the radio frequency semiconductor circuits 511a and 511b and the antennas 512a and 512b to each other. The radio frequency semiconductor circuits 511a and 511b are covered with a resin member 514. Formed on the principal surface (bottom surface in FIG. 12) are: a ground 515 and a first joining frame 516. Further formed at the radio frequency substrate 510 are via holes 517 penetrating through the radio frequency substrate 510 in a thickness direction thereof. The ground 515 is removed at the periphery of opening parts of the via holes 517.

A semiconductor cover substrate 520 is a silicon substrate. Formed on a principal surface (top surface in FIG. 12) of the semiconductor cover substrate 520 are: a silicon integrated circuit 521 and a second joining frame 522. Formed on a surface (bottom surface in FIG. 12) opposite to the principal surface is a ground 523. Further formed at the semiconductor cover substrate 520 are via holes 524 penetrating through the semiconductor cover substrate 520 in a thickness direction thereof. The ground 523 is removed at the periphery of opening parts of the via holes 524.

The joining frame 530 is composed of: the first joining frame 516 formed at the radio frequency substrate 510; and the second joining frame 522 formed at the semiconductor cover substrate 520. In an airtight region laid out by the radio frequency substrate 510, the semiconductor cover substrate 520, and the joining frame 530, the ground 515 on the rear surface of the radio frequency substrate 510 and the silicon integrated circuit 521 of the semiconductor cover substrate 520 are arranged in a manner such as to face each other.

The radio frequency semiconductor circuits 511a and 511b and the silicon integrated circuit 521 are electrically connected to each other through the via holes 517 and bumps 518 in the radio frequency substrate 510. The silicon integrated circuit 521 is electrically connected to wires 541 on the mounting substrate 540 through the via holes 524 in the semiconductor cover substrate 520 and, for example, bumps 525 formed on the rear surface of the semiconductor cover substrate 520.

### Sixth Embodiment

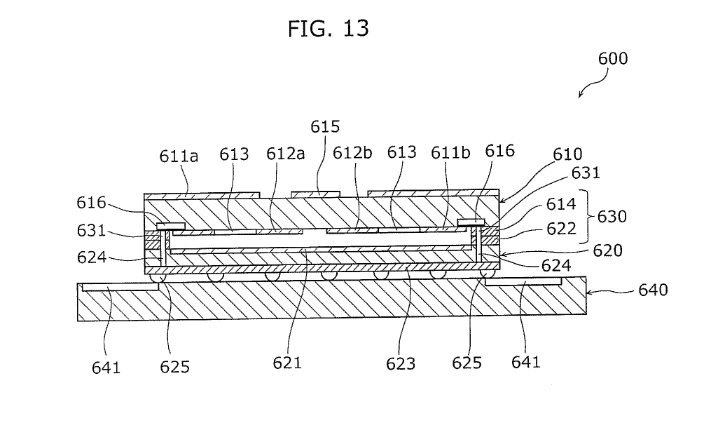

Referring to FIG. 13, a chip size package 600 according to the sixth embodiment of the invention will be described. FIG. 13 is a schematic sectional view of the chip size package 600 according to the sixth embodiment mounted on a mounting substrate 640.

A radio frequency substrate 610 is a sapphire substrate. Formed on a principal surface (bottom surface in FIG. 13) of the radio frequency substrate 610 are: radio frequency semiconductor circuits 611a and 611b; antennas 612a and 612b for transmission and reception; wires 613 electrically connecting the radio frequency semiconductor circuits 611a and 611b and the antennas 612a and 612b to each other; and a first joining frame 614. On a surface opposite to the principal surface, a ground 615 is formed. A portion of the ground 615 overlapping the antennas 612a and 612b is partially removed for antenna radiation and reception.

Formed on a principal surface (top surface in FIG. 13) of a semiconductor cover substrate 620 are: a ground 621 and a second joining frame 622. On a surface (bottom surface in FIG. 13) opposite to the principal surface, a silicon integrated circuit 623 is formed. Further formed at the semiconductor cover substrate 620 are via holes 624 penetrating through the semiconductor cover substrate 620 in a thickness direction thereof.

The joining frame 630 is composed of: the first joining frame 614 formed at the radio frequency substrate 610; and the second joining frame 622 formed at the semiconductor cover substrate 620. Also formed in the joining frame 630 are via holes 631 penetrating through the joining frame 630 in a thickness direction thereof. In an airtight region laid out by the radio frequency substrate 610, the semiconductor cover substrate 620, and the joining frame 630, the radio frequency semiconductor circuits 611a and 611b and the antennas 612a and 612b are arranged.

The semiconductor cover substrate 620 is mounted on the mounting substrate 640 through flip chip mounting with bumps 625 on the silicon integrated circuit 623 in between, and is electrically connected to the wires 641 on the mounting substrate 640 through the bumps 625. The radio frequency semiconductor circuits 611a and 611b and the silicon integrated circuit 623 are electrically connected to each other through wires 616 formed on the principal surface of the radio frequency substrate 610, the via holes 631 in the joining frame 630, and the via holes 624 in the semiconductor cover substrate 620.

### Seventh Embodiment

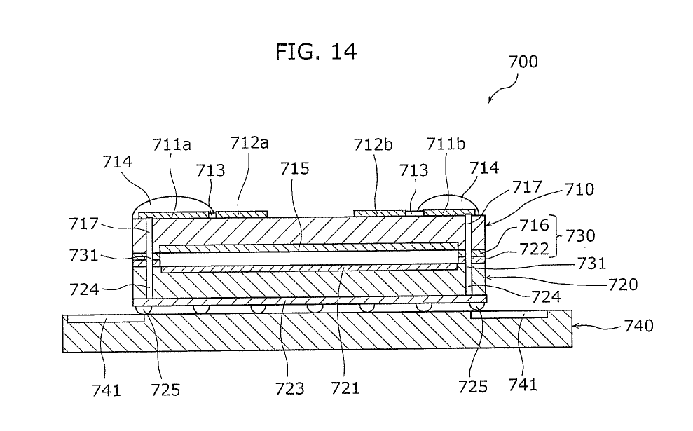

Referring to FIG. 14, a chip size package 700 according to the seventh embodiment of the invention will be described, FIG. 14 is a schematic sectional view of the chip size package 700 according to the seventh embodiment mounted on a mounting substrate 740.

A radio frequency substrate 710 is a sapphire substrate. Formed on a surface (top surface in FIG. 14) opposite to a principal surface of the radio frequency substrate 710 are: radio frequency semiconductor circuits 711a and 711b; antennas 712a and 712b for transmission and reception; and wires 713 electrically connecting the radio frequency semiconductor circuits 711a and 711b and the antennas 712a and 712b to each other. The radio frequency semiconductor circuits 711a and 711b are coated with resin members 714. On the principal surface (bottom surface in FIG. 14) of the radio frequency substrate 710, a ground 715 and a first joining frame 716 are formed. Further formed at the radio frequency substrate 710 are via holes 717 penetrating through the radio frequency substrate 710 in a thickness direction thereof.

Formed on a principal surface (top surface in FIG. 14) of a semiconductor cover substrate 720 are: a ground 721 and a second joining frame 722. On a surface (bottom surface in FIG. 14) opposite to the principal surface, a silicon integrated circuit 723 is formed. Further formed at the semiconductor cover substrate 720 are via holes 724 penetrating through the semiconductor cover substrate 720 in a thickness direction thereof.

A joining frame 730 is composed of: the first joining frame 716 formed at the radio frequency substrate 710; and the second joining frame 722 formed at the semiconductor cover substrate 720. Also formed at the joining frame 630 are via holes 731 penetrating through the joining frame 730 in a thickness direction thereof. In an airtight region laid out by the radio frequency substrate 710, the semiconductor cover substrate 720, and the joining frame 730, grounds 715 and 721 are formed.

The semiconductor cover substrate 720 is mounted on the mounting substrate 740 through flip chip mounting with bumps 725 on the silicon integrated circuit 723 in between, and is electrically connected to wires 741 on the mounting substrate 740 through the bumps 725. The radio frequency semiconductor circuits 711a and 711b and the silicon integrated circuit 723 are electrically connected to each other through the via holes 717 in the radio frequency substrate 710, the via holes 731 in the joining frame 730, and the via holes 724 in the semiconductor cover substrate 720.

### Manufacturing Method of the Embodiment

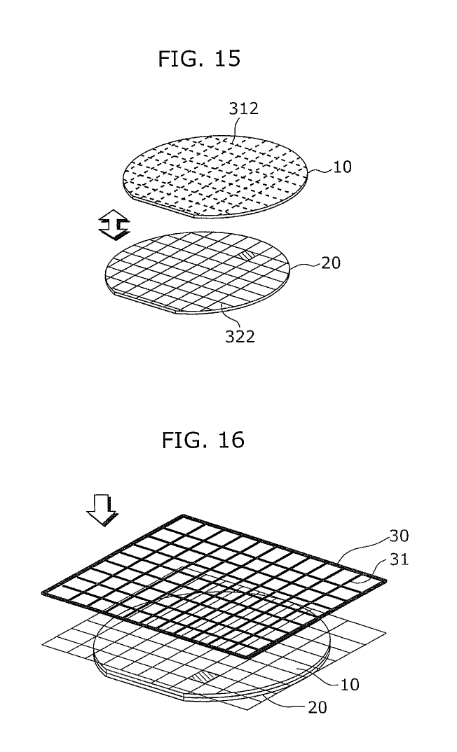

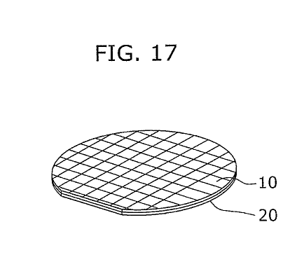

Wafer-level packaging is very useful in terms of cost. The wafer-level packaging is also possible in the embodiments of the invention. Referring to FIGS. 15 to 17, processes of manufacturing the chip size package 300 according to the third embodiment will be described. FIG. 15 is a view showing a state before first and second wafers 10 and 20 are glued to each other. FIG. 16 is a view showing the process of partially heating the first and second wafers 10 and 20 to join the both to other. FIG. 17 is a view showing the process of dicing the joined first and second wafers 10 and 20.

Conventionally, in a case where substrates, such as a sapphire substrate and a silicon substrate, having different thermal expansion coefficients are glued to each other, due to thermal expansion caused by heating and cooling in a joining process, wafer pulverization, reseparation, etc. occur. Thus, with the manufacturing method of this embodiment, the method of partially heating only a wafer joined surface is used to solve this problem. The amount of thermal expansion can be calculated by multiplying the thermal expansion coefficients by areas to be heated and flash temperatures. In this embodiment, favorable gluing with a small amount of thermal expansion can be realized by partially heating only the wafer joined part.

In the manufacturing processes in this embodiment, as shown in FIG. 15, the first wafer 10 as a starting material of the radio frequency substrate 310 and the second wafer 20 as a starting material of the semiconductor cover substrate 320 are first formed independently from each other.

Specifically, formed at the first wafer 10 is the grid-like first joining frame 312 projecting from the principal surface (bottom surface in FIG. 15). For each of a plurality of regions divided by the grid-like first joining frame 312, the radio frequency semiconductor circuits 311a and 311b and the ground 313 are formed on the principal surface, the antennas 316a and 316b, the wires 314, and the grounds 315 are formed on the rear surface, and the via holes 317a, 317b, and 317c are formed inside.

Similarly, formed at the second wafer 20 is the grid-like second joining frame 322 projecting from the principal surface (top surface in FIG. 15). For each of a plurality of regions divided by the grid-like second joining frame 322, the silicon integrated circuit 321 is formed on the principal surface.

Next, as shown in FIG. 16, the first and second wafers 10 and 20 are superposed on each other in a manner such that the first and second joining frames 312 and 322 face each other with the bonding member (not shown in the figure) in between. At this point, they are superposed on each other in a manner such that the first wafer 10 formed of a light-transmissive material (sapphire) is located at the top.

Next, by using a light-blocking mask 30, the first and second wafers 10 and 20 superposed on each other are irradiated with a laser. This light-blocking mask 30 is provided with grid-like slits 31 corresponding to the first and second joining frames 312 and 322 superposed on each other, and thus the laser is selectively irradiated to the first and second joining frames 312 and 322. Used here for laser light can be any laser that radiates light of wavelengths ranging from 10 nm to 1 μm.

Through the laser irradiation, temperatures of the first and second joining frames 312 and 322 rise, whereby the bonding member between the first and second joining frames 312 and 322 melts. Then when this bonding member is solidified again, the first wafer 10 and the second wafer 20 are joined to other.

Next, as shown in FIG. 17, the joined first and second wafers 10 and 20 are diced along the first and second joining frames 312 and 322 whereby the chip size package 300 can be cut out.

Alternatively, upon the laser dicing in a state in which the first and second wafers 10 and 20 are superposed on each other, the joining frames can be heated with heat generated through the laser dicing to thereby achieve the joining. The description refers to the method of performing partial laser irradiation by using the light-blocking mask 30, but with a spot of laser light focused, an irradiation position of the laser light can be operated and moved to thereby partially heat the joined part. Similarly, a wafer position can also be operated and moved. Furthermore, as the partial heating method, use of the laser irradiation has been described, but a method of placing at a top, a bottom, or both parts of the wafer grid-like metal having substantially the same shape as that of the joining part of the semiconductor chip and heating this grid-like metal is also applicable.

Shown as examples of the first and second joining frames 312 and 322 in the aforementioned embodiment are those which have straight sides forming the grid, but they are not limited thereto, and thus the adjacent sides are not necessarily strictly parallel to each other and, for example, may snake their way.

Shown in the aforementioned embodiment is an example where the first joining frame 312 is formed at the first wafer 10 and the second joining frame 322 is formed at the second wafer 20, but a joining frame may be provided at least one of the first and second wafers 10 and 20 and the first and second wafers 10 and 20 may be superposed on each other in a manner such as to sandwich this joining frame.

Furthermore, the method of manufacturing the chip size package 300 according to the third embodiment has been described, and it is needless to say that the chip size packages 400, 500, 600, and 700 according to the other embodiments can also be manufactured by the same method by changing positions, numbers, etc. of semiconductor circuits, wires, grounds, via holes, etc. formed at the first and second wafers 10 and 20.

### [Application]

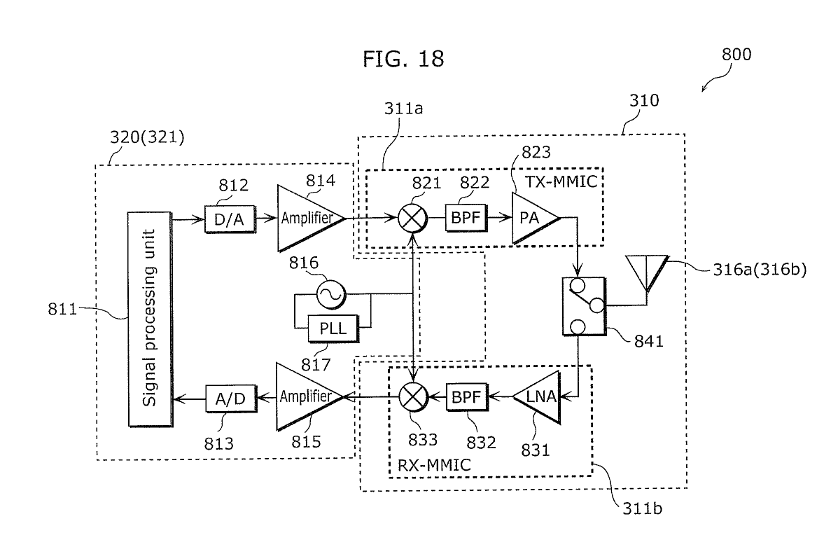

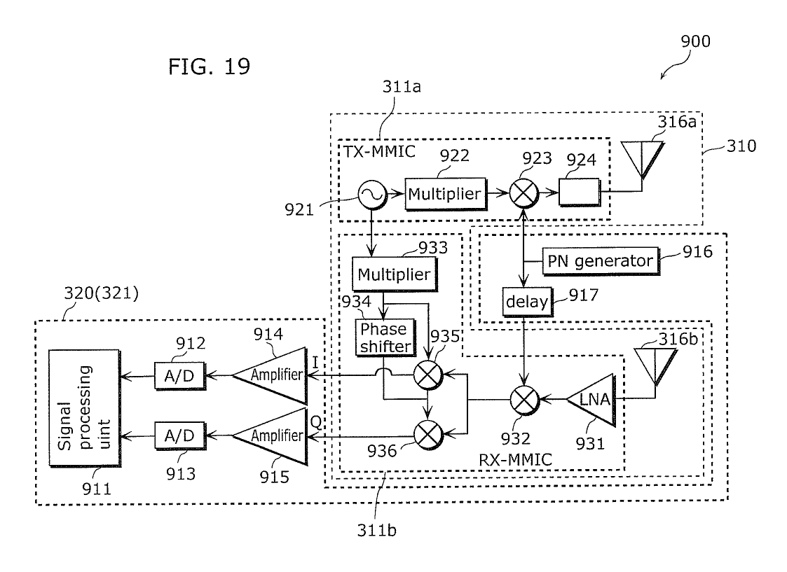

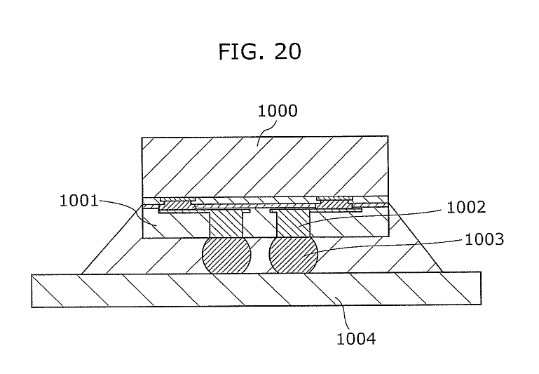

Next, referring to FIGS. 18 and 19, the main application of the chip size package 300 according to the third embodiment of the invention will be described. It is needless to say that the following application is also applicable to the chip size packages 400, 500, 600, and 700 according to the fourth to seventh embodiments.

First, FIG. 18 is a block diagram of a wireless transmitting and receiving device 800. Formed at the radio frequency substrate 310 of the wireless transmitting and receiving device 800 are: the radio frequency semiconductor circuit 311a (TX-MMIC: monolithic microwave integrated circuit for a transmission system); the radio frequency semiconductor circuit 311b (RX-MMIC: monolithic microwave integrated circuit for a reception system) ; and the antenna 316a (316b).

The radio frequency semiconductor circuit 311a for the transmission system includes: a balance modulator 821; a BRP (Band Pass Filter) 822; and a PA (Power Amp) 823. The radio frequency semiconductor circuit 311b for the reception system includes: an LNA (Low Noise Amp) 831; a BPF 832, and a balance modulator 833.

Formed at the semiconductor cover substrate 320 is the silicon integrated circuit 321 including: a signal processing part 811, a D/A (digital-analog converter) 812, an A/D (analog-digital converter) 813, amplifiers 814 and 815, a local oscillator 816, and a PLL (Phase Locked Loop: phase synchronization circuit) 817. The local oscillator 816 or the PLL 817 may be included in either or both of the radio frequency semiconductor circuits 311a and 311b in some cases.

The signal processing part 811 generates transmit data and also performs processing on receive data. The generated transmit data is converted from a digital signal to an analog signal at the D/A 812, is amplified at the amplifier 814, and is reported to the radio frequency semiconductor circuit 311a for the transmission system. On the other hand, the receive data received at the radio frequency semiconductor circuit 311b is amplified at the amplifier 815, is converted from an analog signal to a digital signal at the A/D 813, and inputted to the signal processing part 811.

At the balance modulator 821, an input signal inputted from the amplifier 814 and an oscillation signal inputted from the local oscillator 816 are mixed together (multiplied together). At this point, where a frequency of the oscillation signal supplied from the local oscillator 816 is fc and a frequency of the input signal inputted from the amplifier 814 is f1, main components of an output signal are signals of two frequencies including the signal of the frequency (fc−f1) and the signal of the frequency (fc+f1). An unnecessary component of a signal outputted from the balance modulator 821 is removed at the BPF 822, then amplified at the PA 823, and then delivered onto a wireless line (radio network, radio channel, radio line) from the antenna 316a).

The antenna 316a (316b) can be switched between transmission and reception by a switch 841. That is, upon performing the aforementioned processing, the switch 841 is switched to a transmission side (upper side in FIG. 18). Next, upon reception of the receive data from the wireless line at the antenna 316b, the switch is switched to the transmission side (lower side in FIG. 18). Alternatively, a directional coupler can be used instead of the switch. In this case, transmission and reception can be performed simultaneously.

A signal received at the antenna 316b is amplified at the LNA 831, noise of the signal is removed at the BPF 832, the signal is mixed with (multiplied by) the oscillation signal of the local oscillator 816 at the LNA 831, and is outputted to the silicon integrated circuit 321. This output signal is amplified at the amplifier 815, is converted from the analog signal to a digital signal at the A/D 813, and is processed at the signal processing part 811.

Next, FIG. 19 is a block diagram of a laser device 900 of a spread spectrum type. Formed at a semiconductor cover substrate 320 of the transferred body 900 is a silicon integrated circuit 321 including: a signal processing part 911, A/Ds 912 and 913, amplifiers 914 and 915, a PN generator 916, and a delay 917. Formed at a radio frequency substrate 310 are: a radio frequency semiconductor circuit 311a for transmission system; a radio frequency semiconductor circuit 311b for a reception system; and antennas 316a and 316b on transmission and reception sides, respectively.

The radio frequency semiconductor circuit 311a for the transmission system includes: a local oscillator 921, a multiplier 922, a balance modulator 923, and a BPF 924, and radiates detective electric waves to an object such as an obstacle. The radio frequency semiconductor circuit 311a for the transmission system may be provided with a PA. The radio frequency semiconductor circuit 311b for the reception system includes: an LNA 931, balance modulators 932, 935, and 936, a multiplier 933, and a phase shifter 934, and receives the directive electric waves reflected on the object. Moreover, the antenna 316b on the reception side is connected to the radio frequency semiconductor circuit 311b. The local oscillator 921 may be included in the radio frequency semiconductor circuit 311b or in the silicon integrated circuit 321.

The local oscillator 921 generates an oscillation signal in a microwave band or a millimeter-wave band, and supplies the generated signal to the multipliers 922 and 933. This oscillation signal is multiplied at the multiplier 922 and inputted to the balance modulator 923.

The PN generator 916 generates a PN code based on a timing signal and supplies the generated PN code to the balance modulators 923 and 932. The PN code directed to the balance modulator 932 is delayed in time by the delay 917 before supplied to the balance modulator 932. The “PN code” refers to a binary pseudo noise signal. Used here as one example is an M sequence code well known as the PN code. The PN generator 916 includes a linear feedback shift register with 11 steps, and repeatedly generates and supplies a PN code in a cycle 2047. The balance modulator 923, based on the PN code supplied from the PN generator 916, spreads the signal outputted from the multiplier 922, and outputs a spread signal obtained through spectrum spreading in a wide band. As described above, the balance modulator 923 uses the PN code supplied from the PN generator 916, and performs spread processing on the signal outputted from the multiplier 922. An unnecessary component of the spread signal outputted from the balance modulator 923 is removed at the BPF 924, and then this signal is radiated as directive electric waves from the antenna 316b.

Next, the directive electric waves received at the antenna 316b is inputted to the radio frequency semiconductor circuit 311b for the reception system, and noise such as interrupt electric waves or undesired sound having a frequency component not contributing to laser operation is removed at the LNA 931. At the balance modulator 932, the signal outputted from the LNA 931 is subjected to reverse spreading based on the PN code supplied from the PN generator 916 through the delay 917 to thereby output a reversely spread signal.

At this point, if code delay time t of the PN code supplied to the balance modulator 932 with respect to the PN code supplied to the balance modulator 923 is equal to delay time corresponding to a distance to a detection target, a phase of the PN code included in the received directive electric waves matches a phase of the PN code supplied through the delay 917, and amplitude of the reversely spread signal turns to a peak.

A modulated signal outputted from the balance modulator 932 is inputted to the balance modulators 935 and 936. On the other hand, the oscillation signal outputted from the local oscillator 921 is multiplied (with a multiplication rate of 2×) at the multiplier 933, inputted to the balance modulator 935, also subjected to phase shifting through 90 degrees at the phase shifter 934, and inputted to the balance modulator 936.

At the balance modulator 935, the modulated signal inputted from the balance modulator 932 and the oscillation signal inputted from the multiplier 933 are mixed together (multiplied together) to output an in-phase signal of an intermediate frequency. On the other hand, at the balance modulator 936, the modulated signal inputted from the balance modulator 932 and the oscillation signal inputted from the multiplier 933 through the phase shifter 934 with phase shifted through 90 degrees are mixed together (multiplied together) to output an orthogonal signal of an intermediate frequency.

The in-phase signal outputted from the balance modulator 935 is amplified at the amplifier 914, converted from the analog signal to a digital signal at the A/D 912, and outputted to the signal processing part 911. On the other hand, the orthogonal signal outputted from the balance modulator 936 is amplified at the amplifier 915, converted from the analog single to a digital signal at the A/D 913, and outputted to the signal processing part 911. The signal processing part 911, based on the inputted in-phase signal and orthogonal signal, calculates the code delay time t.

### [Supplementary Description]

In each of the embodiments described above, the radio frequency substrate and its wires form the microstrip wiring structure, but may form a coplanar wiring structure or a grounded coplanar wiring structure. The radio frequency semiconductor circuit is a GaN nitride semiconductor, but may be any other type of semiconductor, such as a GaAs or silicon semiconductor. It has been described that the substrate of the GaN nitride semiconductor as the radio frequency semiconductor circuit is a sapphire substrate, but may be a substrate of any other material such as SiC or Si. It has been described that the semiconductor cover substrate is a silicon semiconductor substrate, but may be any other type of semiconductor substrate. It has been described that the via holes and the connecting posts are located on the radio frequency substrate side that is an inner side than the joining frame, but may be located inside the joining frame.

It has been described that the radio frequency semiconductor circuit corresponds to an LNG and a PA, but may include an active circuit such as a balance modulator (mixer) and a passive element and a passive circuit such as a filter. The radio frequency semiconductor circuit has the two regions: the radio frequency semiconductor circuit (PA) for the transmission system and the radio frequency semiconductor circuit (LNA) for the reception system, but may be formed of one region or two or more regions.

The description refers to the two antennas for transmission and reception, but may refer to one or more antenna groups. It has been described that an antenna structure is a microstrip antenna, but may be any other type of structure such as a slot antenna. The connection between the antenna and the wire may be achieved through any method such as electromagnetic coupling.

The embodiments described above can be combined together in any combination.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

A semiconductor device according to the present invention is very effective as a wireless communication device for high power and high frequencies.

What is claimed is:

1. A semiconductor device comprising:
a radio frequency substrate having a principal surface on which a radio frequency semiconductor circuit is formed;
a semiconductor substrate arranged at a position facing the principal surface of said radio frequency substrate; and
a joining frame arranged between said radio frequency substrate and said semiconductor substrate in a manner such as to surround said radio frequency semiconductor circuit, said joining frame joining said radio frequency substrate to said semiconductor substrate,
wherein said radio frequency substrate further includes a wire formed on a surface opposite to the principal surface, and
said radio frequency semiconductor circuit and said wire are electrically connected to each other through a via hole penetrating through said radio frequency substrate in a thickness direction.

2. The semiconductor device according to claim 1,
wherein said semiconductor substrate is a silicon semiconductor substrate.

3. The semiconductor device according to claim 2,
wherein a gap between said radio frequency semiconductor circuit and said semiconductor substrate is 10 μm or above.

4. The semiconductor device according to claim 2,
wherein said semiconductor substrate has specific resistance larger than 10 Ωcm.

5. The semiconductor device according to claim 3,
wherein a bumpy part is formed on a surface of said semiconductor substrate facing said radio frequency semiconductor circuit.

6. The semiconductor device according to claim 5,
wherein the bumpy part is formed with a plurality of conical projections arranged at a predetermined interval.

7. The semiconductor device according to claim 5,
wherein the bumpy part is a rough surface with a surface roughness of 0.1 μm to 10 μm.

8. The semiconductor device according to claim 3,
wherein an antireflection film preventing reflection of an electric wave discharged from said radio frequency semiconductor circuit is formed on a surface of said semiconductor substrate facing said radio frequency semiconductor circuit.

9. The semiconductor device according to claim 3,
wherein a second semiconductor circuit electrically connected to said radio frequency semiconductor circuit is formed on a surface of said semiconductor substrate facing said radio frequency semiconductor circuit.

10. The semiconductor device according to claim 1,
wherein said radio frequency substrate is any of a sapphire substrate, a nitride semiconductor substrate, a GaAs substrate, an SiC substrate, and a silicon semiconductor substrate.

11. A semiconductor device comprising:
a radio frequency substrate including a radio frequency semiconductor circuit and an antenna electrically connected to said radio frequency semiconductor circuit;
a silicon semiconductor substrate including a second semiconductor circuit electrically connected to said radio frequency semiconductor circuit, said silicon semiconductor substrate having a second surface facing a first surface of said radio frequency substrate; and
a joining frame arranged between the first and second surfaces, said joining frame joining said radio frequency substrate to said silicon semiconductor substrate.

12. The semiconductor device according to claim 11,
wherein said radio frequency semiconductor circuit is formed on the first surface of said radio frequency substrate,
said second semiconductor circuit is formed on the second surface of said silicon semiconductor substrate, and
said radio semiconductor circuit and said second semiconductor circuit are electrically connected to each other through a connecting post.

13. The semiconductor device according to claim 12,
wherein said radio frequency semiconductor circuit and said second semiconductor circuit are arranged inside an airtight region surrounded by said radio frequency substrate, said silicon semiconductor substrate, and said joining frame.

14. The semiconductor device according to claim 13,
wherein said radio frequency substrate further includes a wire formed on a surface opposite to the first surface, and
said radio frequency semiconductor circuit and said wire are electrically connected to each other through the via hole penetrating through said radio frequency substrate.

15. The semiconductor device according to claim 12,
wherein said antenna is formed on a surface opposite to the first surface of said radio frequency substrate, and
said radio frequency semiconductor circuit and said antenna are electrically connected to each other through the via hole penetrating through said radio frequency substrate.

16. The semiconductor device according to claim 15,
wherein said radio frequency semiconductor circuit and said antenna are arranged not to overlap each other.

17. The semiconductor device according to claim 15, further comprising
a mounting substrate joined to the surface opposite to the first surface of said radio frequency substrate,
wherein said mounting substrate includes a through hole formed at a position facing said antenna.

18. The semiconductor device according to claim 13,
wherein said antenna is formed on the first surface and outside of said airtight region.

19. The semiconductor device according to claim 12,
wherein said antenna is formed on the first surface of said radio frequency substrate,
a ground is formed on a surface opposite to the first surface of said radio frequency substrate, and
a slot is formed at a position of said ground overlapping said antenna.

20. The semiconductor device according to claim 11,
wherein said radio frequency semiconductor circuit is formed on a surface opposite to the first surface of said radio frequency substrate, and molded by a resin member.

21. The semiconductor device according to claim 20,
wherein said second semiconductor circuit is formed on the second surface of said silicon semiconductor substrate, and
said radio frequency semiconductor circuit and said second semiconductor circuit are electrically connected to each other through the via hole penetrating through said radio frequency substrate.

22. The semiconductor device according to claim 20,
wherein said second semiconductor circuit is formed on a surface opposite to the second surface of said silicon semiconductor substrate, and
said radio frequency semiconductor circuit and said second semiconductor circuit are electrically connected to each other through a first via hole penetrating through said radio frequency substrate and a second via hole penetrating through said silicon semiconductor substrate.

23. The semiconductor device according to claim 11,
wherein said joining frame is formed by bonding with a bonding member a first joining frame projecting from the first surface of said radio frequency substrate and a second joining frame projecting from the second surface of said silicon semiconductor substrate.

24. The semiconductor device according to claim 10,
wherein said radio frequency substrate is any of a sapphire substrate, a nitride semiconductor substrate, a GaAs sunbstrate, an SiC substrate, and a silicon semiconductor substrate.

25. A semiconductor device manufacturing method of manufacturing the semiconductor device according to claim 1, said semiconductor device manufacturing method comprising:
forming the radio frequency semiconductor circuit in each of a plurality of regions previously laid out on a principal surface of a first wafer serving as a starting material of the radio frequency substrate;
forming, on at least either of the principal surface of the first wafer and a principal surface of a second wafer serving as a starting material of the semiconductor substrate, a joining frame in a manner such as to lay out the plurality of regions;
superposing the first wafer and the second wafer on each other in a manner such as to sandwich the joining frame;
joining the first and second wafers by partially heating the first and second wafers along the joining frame; and
cutting the joined first and second wafers along the joining frame.

26. The semiconductor device manufacturing method according to claim 25,
wherein the joining frame is formed into a grid-like shape in a manner such as to lay out the plurality of regions.

27. The semiconductor device manufacturing method according to claim 25,
wherein the first wafer is formed of a light-transmissive material; and
the first and second wafers are joined to each other by irradiating laser light along the joining frame from a side of the first wafer.

28. The semiconductor device manufacturing method according to claim 27,
wherein the first wafer is a sapphire substrate.

29. A semiconductor device manufacturing method of manufacturing the semiconductor device according to claim 11, said semiconductor device manufacturing method comprising:
forming the radio frequency semiconductor circuit and the antenna in each of a previously laid-out plurality of regions of a first wafer serving as a starting material of the radio frequency substrate;
forming the second semiconductor circuit in each of a previously laid out plurality of regions of a second wafer serving as a starting material of the silicon semiconductor substrate;
forming, ate at least either of the first wafer and the second wafer, a joining frame in a manner such as to lay out the plurality of regions;
superposing the first wafer and the second wafer on each other in a manner such as to sandwich the joining frame;
joining the first and second wafers by partially heating the first and second wafers along the joining frame; and
cutting the joined first and second wafers along the joining frame.

30. The semiconductor device manufacturing method according to claim 29,
wherein the joining frame is formed into a grid-like shape in a manner such as to lay out the plurality of regions.

31. The semiconductor device manufacturing method according to claim 29,
wherein the first wafer is formed of a light transmissive material, and
the first and second wafers are joined to each other by irradiating laser light along the joining frame from a side of the first wafer.

32. The semiconductor device manufacturing method according to claim 31,
wherein the first wafer is a sapphire substrate.
